(19) United States
(12) Patent Application Publication
(10) Pub. No.: US 2025/0391489 A1
(43) Pub. Date: Dec. 25, 2025

(54) DYNAMIC READ ERROR HANDLING USING MEMORY GROUPS

(71) Applicant: Micron Technology, Inc., Boise, ID (US)

(72) Inventors: Jiejuan Liu, Singapore (SG); Yew Shen Teo, Singapore (SG); Wai Leong Chin, Singapore (SG); Jen Hung Liao, Zhubei City (TW)

(21) Appl. No.: 19/219,529

(22) Filed: May 27, 2025

Related U.S. Application Data
(60) Provisional application No. 63/663,311, filed on Jun. 24, 2024.

(51) Int. Cl. G11C 29/52; G11C 16/08; G11C 16/26

(52) U.S. Cl. CPC G11C 29/52; G11C 16/08; G11C 16/26

(57) ABSTRACT

The present disclosure configures a system component, such as a memory sub-system controller, to provide adaptive read error handling operations. The controller receives a request to read data from one or more blocks of a word line group (WGP) stored in a set of memory components. The controller determines, in response to receiving the request to read the data, that a dynamic error handling (ETH) entry is associated with the WGP. The controller retrieves, from the ETH entry, a read offset used to previously decode one or more pages from the WGP and selectively performs a set of read error handling (REH) operations to decode the data from the one or more blocks of the WGP using the read offset retrieved from the ETH entry.

### PRIORITY APPLICATION

This application claims the benefit of priority to U.S. Provisional Application Ser. No. 63/663,311, filed Jun. 24, 2024, which is incorporated herein by reference in its entirety.

### TECHNICAL FIELD

Examples of the disclosure relate generally to memory sub-systems and, more specifically, to providing media management for reading data stored in a set of memory components, such as memory dies or memory blocks.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating an example computing environment including a memory sub-system, in accordance with some examples.

FIG. 2 is a block diagram of an example media operations manager, in accordance with some examples.

FIG. 3 is a block diagram of an example dynamic error handling (ETH) entry, in accordance with some examples.

FIGS. 4-5 are flow diagrams of example methods to perform media management operations, in accordance with some examples.

FIG. 6 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

The present disclosure configures a system component, such as a memory sub-system controller, to dynamically perform memory management operations for reading data from different groups of memory components (e.g., memory dies, planes, word lines, word line groups (WGP), and/or memory blocks or sub-blocks). The memory sub-system controller can track what read offsets and/or read error handling (REH) operations were performed to decode data in an individual group of memory components and store that information in an ETH entry. Using the information stored in the ETH entry, the controller can selectively perform REH operations to subsequently decode and read data from the individual group of memory components. In this way, one or more REH operations can be skipped or not performed when reading data from the same group of memory components in response to subsequent requests, which improves the overall efficiency of operating the memory sub-system.

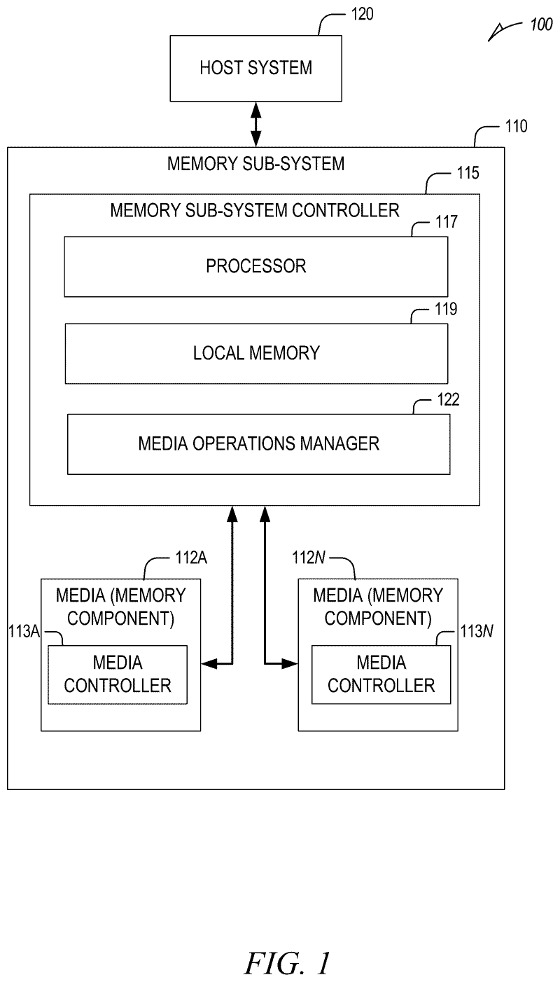

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data”.

The memory sub-system can initiate media management operations, such as a write operation, on host data that is stored on a memory device. For example, firmware of the memory sub-system may re-write previously written host data from a location on a memory device to a new location as part of garbage collection management operations. The data that is re-written, for example as initiated by the firmware, is hereinafter referred to as “garbage collection data” and can be performed periodically for each block stripe (BS) that is stored in the memory sub-system. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management (e.g., read disturb scan operations), different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

NAND flash memory, commonly utilized in a variety of devices from mobile phones to enterprise storage systems, faces significant challenges related to data integrity and operational efficiency as the memory ages. This technology stores data in cells that degrade over time due to repeated use, leading to errors such as bit flips. To maintain data integrity, NAND flash employs several REH and correction mechanisms. These include block family error avoidance (BFEA) bin which stores different read offsets for different block families; CFbyte and CFbit calibration, which adjust read threshold voltages or other read offsets and parameters at the byte and bit levels to enhance reading accuracy; SureARC Calibration, a refinement process that calibrates or adjusts the read offsets at the valley level; Assurance ARC, which ensures data integrity through enhanced error correction during read operations, such as by further adjusting the read offsets at the valley level; 2-bit Corrective Read (2bCR), correcting up to two bits of aggressor bits in an adjacent WL; 4-bit Corrective Read (2bCR), correcting up to four bits of aggressor bits in an adjacent WL; and Redundant Array of Independent NAND (RAIN), providing data redundancy and enhancing error recovery. Corrective Read (CR) is used in attempt to readout the correct data where a normal read operation could not recover the data within ECC limit. The CR is a NAND feature that allows cell-by-cell adjustment of read offsets based on each cell's primary aggressor, its adjacent cells in the adjacent WLs. The 2bCR and 4bCR can require different read strobes on aggressor WLs and provide different corrective capability.

Each of these REH operations consumes additional computational resources and time, leading to operational inefficiencies. Multiple read cycles are often utilized, as initial unsuccessful reads prompt the engagement of more sophisticated mechanisms like CFbit calibration or SureARC, each necessitating new read attempts. This not only increases latency, significantly impacting data access times, but also consumes additional power and processing capacity, reducing overall system efficiency.

The impact of aging on NAND flash exacerbates these issues. As NAND cells wear out, the frequency and severity of errors increase, leading to a higher reliance on error correction and handling mechanisms. This results in an increased frequency of engaging mechanisms like 2bCR and RAIN, further slowing down the system and necessitating repeated recalibrations and error checks, such as Sure Arc and CFbit calibrations. These factors collectively contribute to reduced operational efficiency and reduce the usable life of NAND flash memory.

The present disclosure addresses the above and other deficiencies by providing a memory controller that can dynamically control whether certain REH operations are performed for reading data from an individual WGP. The memory sub-system controller can track what read offsets and/or REH operations were performed to successfully decode data in an individual group of memory components and store that information in an ETH entry. Using the information stored in the ETH entry, the controller can selectively perform (or not perform) REH operations (e.g., certain REH operations can be omitted, skipped or excluded) to subsequently decode and read data from the individual group of memory components. By avoiding performing one or more REH operations when reading data from the same group of memory components in response to subsequent requests, the overall efficiency of operating the memory sub-system is improved.

For some examples, the memory sub-system (e.g., memory sub-system controller) receives a request to read data from one or more blocks of a WGP stored in the set of memory components. The controller can determine, in response to receiving the request to read the data, that a dynamic error handling (ETH) entry is associated with the WGP and can retrieve, from the ETH entry, a read offset used to previously decode one or more pages from the WGP. The controller can selectively perform a set of REH operations to decode the data from the one or more blocks of the WGP using the read offset retrieved from the ETH entry.

The controller can, prior to receiving the request, receive a prior request to read the one or more pages of data from a set of blocks of the WGP. The controller can determine, in response to receiving the prior request, that the ETH entry is unavailable for the WGP and, in response to determining that the ETH entry is unavailable for the WGP, can perform each REH operation in the set of REH operations to read the one or more pages. In some examples, the ETH entry has not been created for the WGP when the prior request is received.

In some examples, the controller can determine the read offset based on performing each of the REH operations in the set of REH operations and determines a last REH operation in the set of REH operations that resulted in successfully decoding the one or more pages of the set of blocks. In some cases, the controller generates the ETH entry to include the determined read offset and the last REH operation that resulted in successfully decoding the one or more pages of the set of blocks. The controller stores, in the ETH entry, an identifier of the WGP and an identifier of a plane storing the one or more pages of the set of blocks. The set of REH operations can include a first read offset determination based on BFEA bin, a second read offset determination based on CFbyte, a third read offset determination based on CFbit calibration, one or more read offset valley adjustments, one or more first types of bit error correction code (ECC) operations, and one or more second types of ECC operations.

The controller can search a plurality of WGPs stored in a list of ETH entries to identify the ETH entry having a WGP that corresponds to the WGP associated with the request to read the data. In some cases, the controller can perform a first REH operation in the set of REH operations including reading a first page of the one or more blocks using the read offset retrieved from the ETH entry and determining whether the first page has been successfully decoded using the first REH operation. In some examples, the controller, in response to determining that the first page has unsuccessfully been decoded, retrieves, from the ETH entry, a last REH operation in the set of REH operations that resulted in successfully previously decoding the one or more pages and performs the last REH operation retrieved from the ETH entry to decode the first page.

The controller can determine that the first page has been successfully decoded using the last REH operation. In response, the controller decodes one or more additional pages using the last REH operation. In some examples, the controller determines that the first page has been unsuccessfully decoded using the last REH operation. In such cases, in response to determining that the first page has been unsuccessfully decoded using the last REH operation, the controller can perform one or more read offset valley adjustments based on the read offset retrieved from the ETH entry to decode the first page using a new read offset.

The controller can determine that the first page has been successfully decoded using the one or more read offset valley adjustments. In such cases, the controller can, in response to determining that the first page has been successfully decoded using the one or more read offset valley adjustments, update the read offset stored in the ETH entry using the new read offset. In some cases, the one or more read offset valley adjustments include multiple types of valley adjustment operations (e.g., SureArc calibration and Assurance ARC calibration).

In some examples, the controller can determine that the first page has been unsuccessfully decoded using the one or more read offset valley adjustments. The controller can perform each REH operation in the set of REH operations to read the first page in response to determining that the first page has been unsuccessfully decoded using the one or more read offset valley adjustments. In some cases, the controller updates the ETH entry in response to performing each REH operation in the set of REH operations to read the first page.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies).

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components. An example of non-volatile memory components includes NOR- and (NAND)-type flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory.

In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), (NOR) flash memory, electrically erasable programmable read-only memory (EEPROM), and a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages, WLs, WGPs, planes, blocks, or sub-blocks that can refer to a unit of the memory component 112 used to store data. In general, the memory pages, WLs, WGPs, sub-blocks, and/or blocks are collectively or individually referred to as memory components.

The memory sub-system controller 115 can communicate with the memory components 112A to 112N to perform operations such as reading data, writing data, or erasing data at the memory components 112A to 112N and other such operations. The memory sub-system controller 115 can communicate with the memory components 112A to 112N to perform various memory management operations, such as different scan rates, different scan frequencies, different wear leveling, different read disturb management operations, such as read disturb scan operations, different near miss ECC operations, folding operations, preventing folding operations from being performed, and/or different dynamic data refresh operations.

The memory sub-system controller 115 can include hardware such as one or more integrated circuits and/or discrete components, one or more thermometers (used to measure a current operating temperature of the memory sub-system 110 and/or the memory components 112A to 112N or ambient temperature), a buffer memory, and/or a combination thereof. In some examples, the output of the one or more thermometers can be used to determine a current write temperature to be stored in association with data on the memory components 112A to 112N.

The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some examples, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another example, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands, requests, or operations from the host system 120 and can convert the commands, requests, or operations into instructions or appropriate commands to achieve the desired access to the memory components 112A to 112N. In some examples, the commands or operations received from the host system 120 can specify configuration data for the memory components 112A to 112N. The configuration data can include a table that specifies the WGPs or other grouping information for the data stored in the set of memory components 112A to 112N.

The memory sub-system controller 115 can be responsible for other memory management operations, such as wear leveling operations, garbage collection operations, error detection and error-correcting code (ECC) operations, encryption operations, caching operations, media scans (where different block stripes are read and analyzed for errors to determine whether to refresh or fold the block stripe), data refreshing, read disturb operations, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some examples, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which is a raw memory device combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

The memory sub-system controller 115 can include a media operations manager 122. The media operations manager 122 can be configured to provide adaptive read error handling operations. The media operations manager 122 receives a request to read data from one or more blocks of a WGP stored in a set of memory components. The media operations manager 122 determines, in response to receiving the request to read the data, that a ETH entry is associated with the WGP. The media operations manager 122 retrieves, from the ETH entry, a read offset used to previously decode one or more pages from the WGP and selectively performs a set of REH operations to decode the data from the one or more blocks of the WGP using the read offset retrieved from the ETH entry.

Depending on the examples, the media operations manager 122 can comprise logic (e.g., a set of transitory or non-transitory machine instructions, such as firmware) or one or more components that cause the media operations manager 122 to perform operations described herein. The media operations manager 122 can comprise a tangible or non-tangible unit capable of performing operations described herein. Further details with regard to the operations of the media operations manager 122 are described below.

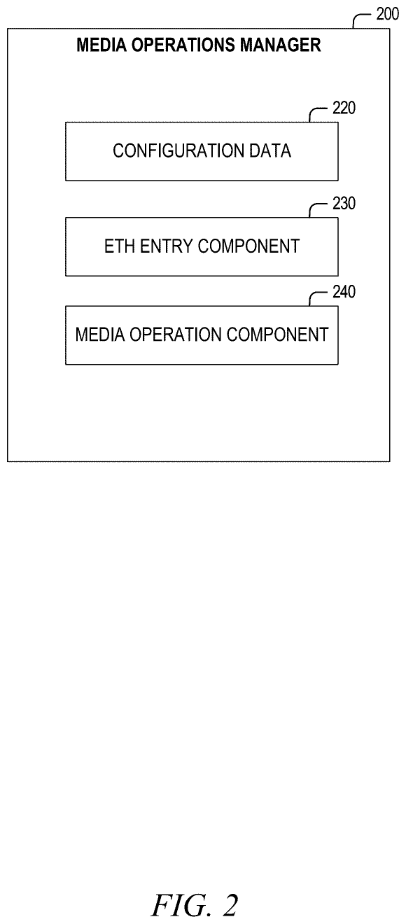

FIG. 2 is a block diagram of an example media operations manager 200 (corresponding to media operations manager 122), in accordance with some examples. As illustrated, the media operations manager 200 includes configuration data 220, an ETH entry component 230, and a media operation component 240. For some examples, the media operations manager 122 can differ in components or arrangement (e.g., less or fewer components) from what is illustrated in FIG. 2.

The configuration data 220 accesses and/or stores configuration data associated with the memory components 112A to 112N. In some examples, the configuration data 220 is programmed into the media operations manager 122. For example, the media operations manager 122 can communicate with the memory components 112A to 112N to obtain the configuration data and store the configuration data 220 locally on the media operations manager 122. In some examples, the media operations manager 122 communicates with the host system 120. The host system 120 receives input from an operator or user that specifies parameters including the WGPs, different bins, groups, blocks, WLs, memory dies, and/or sets of the memory components 112A to 112N. The media operations manager 122 receives the configuration data from the host system 120 and stores the configuration data in the configuration data 220.

The media operation component 240 can receive a request to read a set of data that is stored in the set of memory components 112A to 112N, such as from the host system 120. In response, the media operation component 240 can selectively perform one or more REH operations in the process of reading and decoding the data. Specifically, the media operation component 240 can selectively exclude certain REH operations if the data is being read from a WGP that is associated with one or more ETH entries. In some examples, the media operation component 240 can determine the WGP in which at least a portion of the data being requested to be read is stored or programmed. The media operation component 240 can search a list of ETH entries to find or determine whether an ETH entry has previously been generated and stored for the WGP.

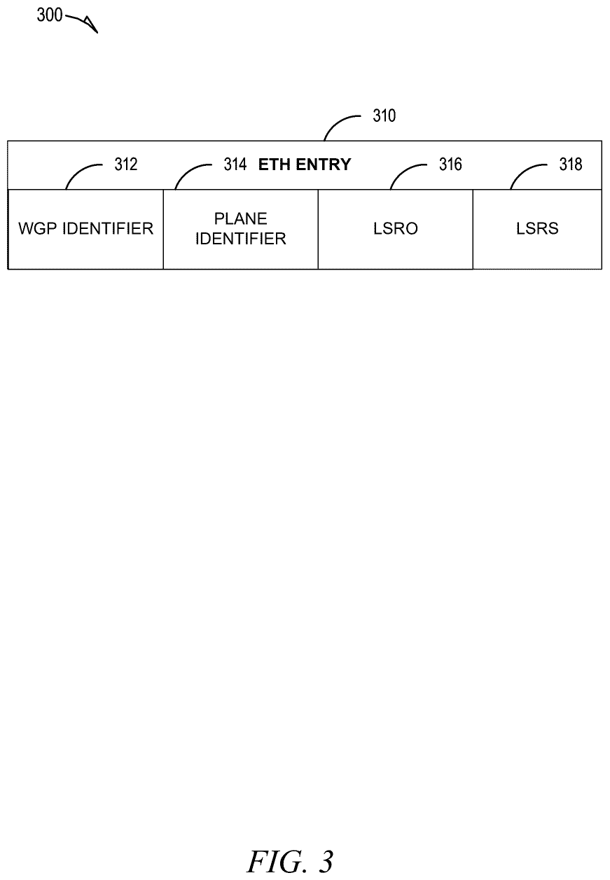

In some examples, the media operation component 240 can search WGP identifiers 312 of each ETH entry 310, shown in the diagram 300 of FIG. 3. The media operation component 240 can determine whether the WGP identifier 312 of a particular ETH entry 310 matches or corresponds to the WGP that stores at least a portion of the data requested to be read. In response to determining that none of the ETH entries 310 include a matching WGP identifiers 312, the media operation component 240 performs normal (default) reading/decoding operations in which each of a set of REH operations is performed to read/decode the data. Specifically, the media operation component 240 can obtain a default or known read offset (e.g., threshold voltage level) corresponding to a BFEA bin associated with the storage location of the data being read. Then, the media operation component 240 can perform CFbyte and/or CFbit operations to refine or adjust the read offset. The media operation component 240 can then perform one or more valley adjustment operations, such as SureArc and/or Arc operations to refine the read offset. The media operation component 240 can also perform 2bCR, hard bit decoding and/or 4bCR and also RAIN operations to correct the data being read. The media operation component 240 can stop performing subsequent REH operations when any one of these REH operations successfully decodes the data from the storage location.

After reading and decoding the data by performing each of the REH operations or portion thereof needed to successfully decode the data, the media operation component 240 can communicate with the ETH entry component 230 to generate and store a new ETH entry for the WGP. The media operation component 240 can provide an identifier of the WGP, which is stored by the media operation component 240 in the WGP identifiers 312 of the new ETH entry. The media operation component 240 can also provide one or more plane identifiers representing the planes that were successfully read/decoded. These one or more plane identifiers are stored in the plane identifier field 314 of the new ETH entry. The ETH entry component 230 can also store in the LSRO field 316 of the new ETH entry, the read offset that was used to successfully decode the data. The ETH entry component 230 can also store in the LSRS field 318 an identifier of the last REH operation that was performed to successfully decode the data.

Subsequently or at another time, the media operation component 240 can receive a request to read an additional set of data from the set of memory components 112A to 112N. In response, the media operation component 240 can communicate with the ETH entry component 230 to determine whether a WGP of the additional set of data matches any WGP identifier stored in the WGP identifiers 312 of ETH entries 310. The ETH entry component 230 can return the ETH entry 310 having the matching WGP identifier 312 to the media operation component 240. The media operation component 240 can then use the information stored in the ETH entry 310 to read and decode the additional set of data using fewer REH operations than previously read data from the same WGP.

For example, the media operation component 240 can retrieve the previously used read offset level stored in the LSRO field 316 from the ETH entry 310. The media operation component 240 can then read or re-read a first portion (e.g., a first page of data) of the data from one or more storage locations of the additional set of data using the previously used read offset level (the read offset used to successfully read and decode data from the same WGP) stored in the LSRO field 316. The media operation component 240 can determine whether the data is successfully decoded using the previously used read offset level. If so, the media operation component 240 can then read a second portion (e.g., a second page of data) from the one or more storage locations of the additional set of data using the previously used read offset level and can continue doing so until data is unsuccessfully decoded. At that point (e.g., in response to determining that using the previously used read offset level to read one or more portions, such as a third page, of the data from the same WGP results in unsuccessful decoding or a failed REH operation), the media operation component 240 can obtain an identifier of the last REH operation used to decode data from the WGP stored in the LSRS field 318.

For example, the media operation component 240 can apply a 2bCR REH operation to decode the one or more portions of the data (e.g., a third page) using the last REH operation. The media operation component 240 can determine whether the third page is successfully decoded using the last REH operation and the 2bCR REH operation. If so, the media operation component 240 continues decoding additional portions using the same REH operation and the 2bCR REH operation. If the third page is unsuccessfully decoded, the media operation component 240 can perform one or more valley adjustments (e.g., an ARC valley adjustment) to the read offset level and can attempt to read the data using the adjusted read offset level. The media operation component 240 can determine that the third page is successfully decoded using the adjusted read offset level. In response, the media operation component 240 updates the fields (e.g., the LSRO field 316 and/or the LSRS field 318) of the ETH entry 310 associated with the WGP.

The media operation component 240 can determine that the decoding of the third page using the adjusted read offset level has failed. In response, the media operation component 240 can perform further valley adjustments using another type of valley adjustment process along with 2bCR to re-read the third page. The media operation component 240 can determine that the third page is successfully decoded using the further adjusted read offset level and the 2bCR. In response, the ETH entry component 230 updates the fields (e.g., the LSRO field 316 and/or the LSRS field 318) of the ETH entry 310 associated with the WGP with the new read offset level and the indication of the last REH operation performed to successfully read/decode data from the WGP.

In some cases, the media operation component 240 can determine that the decoding of the third page using the adjusted read offset level and the 2bCR has failed. In such cases, the media operation component 240 can read and decode the third page using default REH operations (discussed above). The media operation component 240 can then communicate new parameters resulting from applying the default REH operations to the ETH entry component 230 to update the corresponding ETH entry 310.

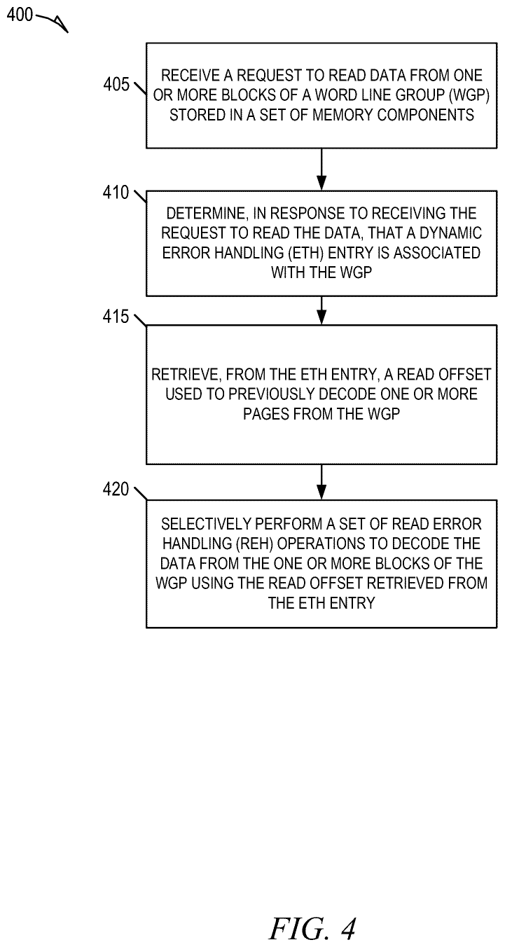

FIG. 4 is a flow diagram of an example method 400 to perform media management operations, in accordance with some examples. The method 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 400 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 4, the method (or process) 400 begins at operation 405, with a media operations manager 122 of a memory sub-system 110 receiving a request to read data from one or more blocks of a WGP stored in a set of memory components. At operation 410, the media operations manager 122 of the memory sub-system 110 determines, in response to receiving the request to read the data, that an ETH entry is associated with the WGP. Thereafter, at operation 415, the media operations manager 122 retrieves, from the ETH entry, a read offset used to previously decode one or more pages from the WGP and, at operation 420, selectively performing a set of REH operations to decode the data from the one or more blocks of the WGP using the read offset retrieved from the ETH entry.

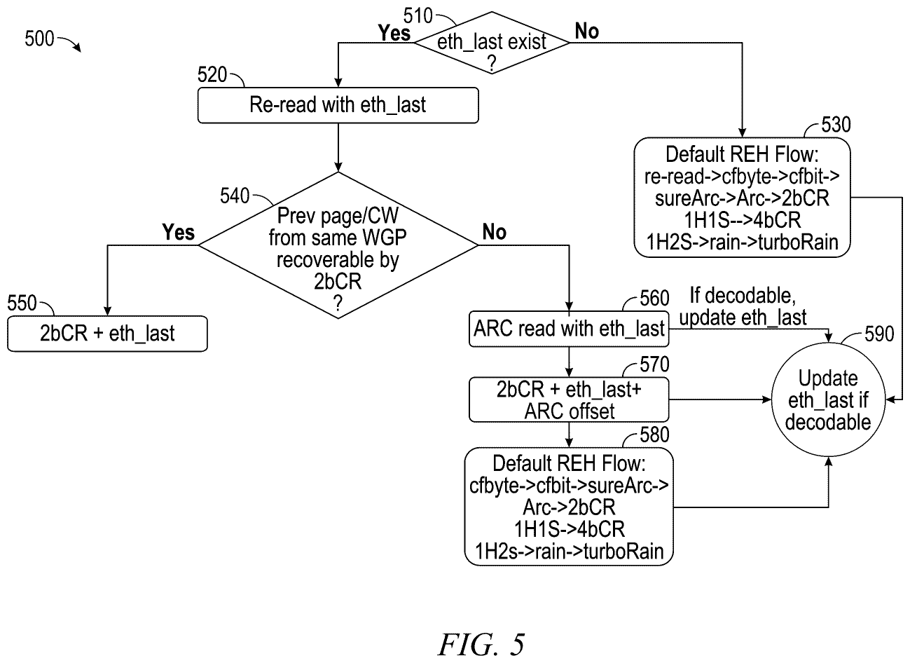

FIG. 5 is a flow diagram of an example method 500 to perform media management operations, in accordance with some examples. The method 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 500 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 5, the method (or process) 500 begins at operation 510 where the media operations manager 200 (e.g., the firmware of the memory sub-system 110) receiving a request to read a set of data from the set of memory components 112A to 112N (e.g., a WGP). The media operations manager 200 can search a set of ETH entries 310 to determine whether an ETH exists for the WGP being read. If so, the media operations manager 200 proceeds to operation 520 and, if not, the media operations manager 200 proceeds to operation 530. At operation 530, the media operations manager 200 uses a set of default REH operations to read the data stored in the WGP of the set of memory components 112A to 112N. For example, the media operations manager 200 can obtain a default or known read offset (e.g., threshold voltage level) corresponding to a BFEA bin associated with the storage location of the data being read. Then, the media operations manager 200 can perform CFbyte and/or CFbit operations to refine or adjust the read offset. The media operations manager 200 can then perform one or more valley adjustment operations, such as SureArc and/or Arc operations to refine the read offset. The media operations manager 200 can also perform 2bCR, hard bit decoding and/or 4bCR and also RAIN operations to correct the data being read. The media operations manager 200 can stop performing subsequent REH operations when any one of these REH operations successfully decodes the data from the storage location.

After performing the operation 530, the media operations manager 200 can generate an ETH entry 310 for the WGP at operation 590 or update an existing one. In some cases, the media operations manager 200 can obtain the last used read offset level at operation 520 to read the set of data from the WGP. The media operations manager 200 can determine whether the last used read offset successfully decodes the data. If so, the media operations manager 200 continues decoding additional portions of the data until the decoding fails. At that point, the media operations manager 200 performs operation 540 where a determination is made as to whether 2bCR decoding was successfully used to decode a portion of data stored in the same WGP. If so, the media operations manager 200 performs operation 550 to decode the current set of data using the 2bCR decoding process of the set of REH operations. The media operations manager 200 continues decoding additional portions using the 2bCR decoding process until decoding fails. At that point, the media operations manager 200 performs operation 560 where the read level offset is adjusted using a valley adjustment process.

The media operations manager 200 determines whether the data stored in the WGP is successfully decoded using the adjusted read level offset. If so, the media operations manager 200 updates the information (e.g., the LSRO field 316 and/or the LSRS field 318) stored in the ETH entry 310 for the WGP and continues decoding the data. If the data is unsuccessfully decoded using the adjusted read level offset, the media operations manager 200 performs operation 570 where the adjusted read level offset is used in conjunction with 2bCR or 4bCR to read and decode the data. Data stored in the ETH entry 310 is updated at operation 590 if the data is successfully decoded. If not, the media operations manager 200 performs operation 580 where the default REH operations are performed to decode the data and the ETH entry 310 is updated using the results of decoding the data using the default REH operations.

In view of the disclosure above, various examples are set forth below. It should be noted that one or more features of an example, taken in isolation or combination, should be considered within the disclosure of this application.

Example 1. A system comprising: a set of memory components of a memory sub-system; and a processing device operatively coupled to the set of memory components, the processing device being configured to perform operations comprising: receiving a request to read data from one or more blocks of a word line group (WGP) stored in the set of memory components; determining, in response to receiving the request to read the data, that a dynamic error handling (ETH) entry is associated with the WGP; retrieving, from the ETH entry, a read offset used to previously decode one or more pages from the WGP; and selectively performing a set of read error handling (REH) operations to decode the data from the one or more blocks of the WGP using the read offset retrieved from the ETH entry.

Example 2. The system of Example 1, the operations comprising: prior to receiving the request, receiving a prior request to read the one or more pages data from a set of blocks of the WGP; determining, in response to receiving the prior request, that the ETH entry is unavailable for the WGP; and in response to determining that the ETH entry is unavailable for the WGP, performing each REH operation in the set of REH operations to read the one or more pages.

Example 3. The system of Example 2, wherein the ETH entry has not been created for the WGP when the prior request is received.

Example 4. The system of any one of Examples 2-3, the operations comprising: determining the read offset based on performing each of the REH operations in the set of REH operations; and determining a last REH operation in the set of REH operations that resulted in successfully decoding the one or more pages of the set of blocks.

Example 5. The system of Example 4, the operations comprising: generating the ETH entry to include the determined read offset and the last REH operation that resulted in successfully decoding the one or more pages of the set of blocks; and storing in the ETH entry an identifier of the WGP and an identifier of a plane storing the one or more pages of the set of blocks.

Example 6. The system of any one of Examples 2-5, wherein the set of REH operations comprises a first read offset determination based on block family error avoidance (BFEA) bin, a second read offset determination based on CFbyte, a third read offset determination based on CFbit calibration, one or more read offset valley adjustments, one or more first types of bit error correction code (ECC) operations, and one or more second types of ECC operations.

Example 7. The system of any one of Examples 1-6, the operations comprising: searching a plurality of WGPs stored in a list of ETH entries to identify the ETH entry having a WGP that corresponds to the WGP associated with the request to read the data.

Example 8. The system of Example 7, the operations comprising: performing a first REH operation in the set of REH operations comprising reading a first page of the one or more blocks using the read offset retrieved from the ETH entry; and determining whether the first page has been successfully decoded using the first REH operation.

Example 9. The system of Example 8, the operations comprising: in response to determining that the first page has unsuccessfully been decoded, retrieving, from the ETH entry, a last REH operation in the set of REH operations that resulted in successfully previously decoding the one or more pages; and perform the last REH operation retrieved from the ETH entry to decode the first page.

Example 10. The system of Example 9, the operations comprising: determining that the first page has been successfully decoded using the last REH operation; and in response to determining that the first page has been successfully decoded using the last REH operation, decoding one or more additional pages using the last REH operation.

Example 11. The system of any one of Examples 9-10, the operations comprising: determining that the first page has been unsuccessfully decoded using the last REH operation; and in response to determining that the first page has been unsuccessfully decoded using the last REH operation, performing one or more read offset valley adjustments based on the read offset retrieved from the ETH entry to decode the first page using a new read offset.

Example 12. The system of Example 11, the operations comprising: determining that the first page has been successfully decoded using the one or more read offset valley adjustments; and in response to determining that the first page has been successfully decoded using the one or more read offset valley adjustments, updating the read offset stored in the ETH entry using the new read offset.

Example 13. The system of Example 12, wherein the one or more read offset valley adjustments comprise multiple types of valley adjustment operations.

Example 14. The system of any one of Examples 12-13, the operations comprising: determining that the first page has been unsuccessfully decoded using the one or more read offset valley adjustments; and performing each REH operation in the set of REH operations to read the first page in response to determining that the first page has been unsuccessfully decoded using the one or more read offset valley adjustments.

Example 15. The system of Example 14, the operations comprising: updating the ETH entry in response to performing each REH operation in the set of REH operations to read the first page.

Methods and computer-readable storage medium with instructions for performing any one of the above Examples.

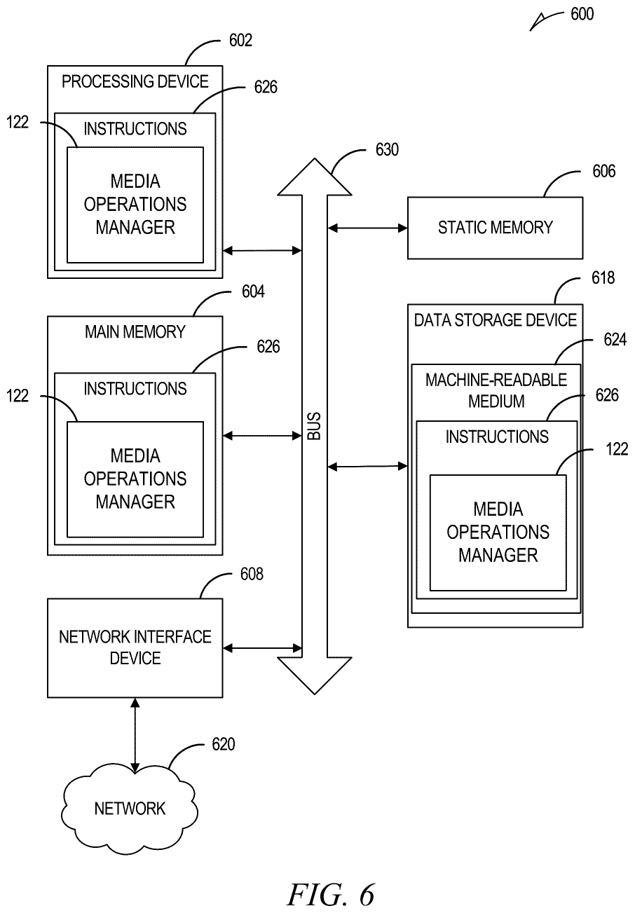

FIG. 6 illustrates an example machine in the form of a computer system 600 within which a set of instructions can be executed for causing the machine to perform any one or more of the methodologies discussed herein. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), a network processor, or the like. The processing device 602 is configured to execute instructions 626 for performing the operations and steps discussed herein. The computer system 600 can further include a network interface device 608 to communicate over a network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 implement functionality corresponding to the media operations manager 122 of FIG. 1. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, examples of the disclosure have been described with reference to specific example embodiments thereof. It will be evident that various modifications can be made thereto without departing from the broader examples of the disclosure as set forth in the following claims. The specification and drawings are, accordingly, to be regarded in an illustrative sense rather than a restrictive sense.

What is claimed is:

1. A system comprising:
a set of memory components; and
a processing device operatively coupled to the set of memory components, the processing device being configured to perform operations comprising:
receiving a request to read data from one or more blocks of a word line group (WGP) stored in the set of memory components;
determining, in response to receiving the request to read the data, that a dynamic error handling (ETH) entry is associated with the WGP;
retrieving, from the dynamic ETH entry, a read offset used to previously decode one or more pages from the WGP; and
selectively performing a set of read error handling (REH) operations to decode the data from the one or more blocks of the WGP using the read offset retrieved from the dynamic ETH entry.

2. The system of claim 1, the operations comprising:
prior to receiving the request, receiving a prior request to read the one or more pages data from a set of blocks of the WGP;
determining, in response to receiving the prior request, that the dynamic ETH entry is unavailable for the WGP; and
in response to determining that the dynamic ETH entry is unavailable for the WGP, performing each REH operation in the set of REH operations to read the one or more pages.

3. The system of claim 2, wherein the dynamic ETH entry has not been created for the WGP when the prior request is received.

4. The system of claim 2, the operations comprising:
determining the read offset based on performing each of the REH operations in the set of REH operations; and
determining a last REH operation in the set of REH operations that resulted in successfully decoding the one or more pages of the set of blocks.

5. The system of claim 4, the operations comprising:
generating the dynamic ETH entry to include the determined read offset and the last REH operation that resulted in successfully decoding the one or more pages of the set of blocks; and
storing in the dynamic ETH entry an identifier of the WGP and an identifier of a plane storing the one or more pages of the set of blocks.

6. The system of claim 2, wherein the set of REH operations comprises a first read offset determination based on block family error avoidance (BFEA) bin, a second read offset determination based on CFbyte, a third read offset determination based on CFbit calibration, one or more read offset valley adjustments, one or more first types of bit error correction code (ECC) operations, and one or more second types of ECC operations.

7. The system of claim 1, the operations comprising:
searching a plurality of WGPs stored in a list of dynamic ETH entries to identify the dynamic ETH entry having a WGP that corresponds to the WGP associated with the request to read the data.

8. The system of claim 7, the operations comprising:
performing a first REH operation in the set of REH operations comprising reading a first page of the one or more blocks using the read offset retrieved from the dynamic ETH entry; and
determining whether the first page has been successfully decoded using the first REH operation.

9. The system of claim 8, the operations comprising:
in response to determining that the first page has unsuccessfully been decoded, retrieving, from the dynamic ETH entry, a last REH operation in the set of REH operations that resulted in successfully previously decoding the one or more pages; and
perform the last REH operation retrieved from the dynamic ETH entry to decode the first page.

10. The system of claim 9, the operations comprising:
determining that the first page has been successfully decoded using the last REH operation; and
in response to determining that the first page has been successfully decoded using the last REH operation, decoding one or more additional pages using the last REH operation.

11. The system of claim 9, the operations comprising:
determining that the first page has been unsuccessfully decoded using the last REH operation; and
in response to determining that the first page has been unsuccessfully decoded using the last REH operation, performing one or more read offset valley adjustments based on the read offset retrieved from the dynamic ETH entry to decode the first page using a new read offset.

12. The system of claim 11, the operations comprising:
determining that the first page has been successfully decoded using the one or more read offset valley adjustments; and
in response to determining that the first page has been successfully decoded using the one or more read offset valley adjustments, updating the read offset stored in the dynamic ETH entry using the new read offset.

13. The system of claim 12, wherein the one or more read offset valley adjustments comprise multiple types of valley adjustment operations.

14. The system of claim 12, the operations comprising:
determining that the first page has been unsuccessfully decoded using the one or more read offset valley adjustments; and
performing each REH operation in the set of REH operations to read the first page in response to determining that the first page has been unsuccessfully decoded using the one or more read offset valley adjustments.

15. The system of claim 14, the operations comprising:
updating the dynamic ETH entry in response to performing each REH operation in the set of REH operations to read the first page.

16. A method comprising:
receiving a request to read data from one or more blocks of a word line group (WGP) stored in a set of memory components;
determining, in response to receiving the request to read the data, that a dynamic error handling (ETH) entry is associated with the WGP;
retrieving, from the dynamic ETH entry, a read offset used to previously decode one or more pages from the WGP; and
selectively performing a set of read error handling (REH) operations to decode the data from the one or more blocks of the WGP using the read offset retrieved from the dynamic ETH entry.

17. The method of claim 16, comprising:
prior to receiving the request, receiving a prior request to read the one or more pages data from a set of blocks of the WGP;
determining, in response to receiving the prior request, that the dynamic ETH entry is unavailable for the WGP; and
in response to determining that the dynamic ETH entry is unavailable for the WGP, performing each REH operation in the set of REH operations to read the one or more pages.

18. The method of claim 17, wherein the dynamic ETH entry has not been created for the WGP when the prior request is received.

19. The method of claim 17, comprising:
determining the read offset based on performing each of the REH operations in the set of REH operations; and
determining a last REH operation in the set of REH operations that resulted in successfully decoding the one or more pages of the set of blocks.

20. A non-transitory computer-readable storage medium comprising instructions that, when executed by a processing device, cause the processing device to perform operations comprising:
receiving a request to read data from one or more blocks of a word line group (WGP) stored in a set of memory components;
determining, in response to receiving the request to read the data, that a dynamic error handling (ETH) entry is associated with the WGP;
retrieving, from the dynamic ETH entry, a read offset used to previously decode one or more pages from the WGP; and
selectively performing a set of read error handling (REH) operations to decode the data from the one or more blocks of the WGP using the read offset retrieved from the dynamic ETH entry.
